(19) United States
(12) Patent Application Publication
(10) Pub. No.: US 2017/0069802 A1
(43) Pub. Date: Mar. 9, 2017

(54) LIGHT EMITTING DEVICE INCLUDING QUANTUM DOTS

(71) Applicant: QD VISION, INC., LEXINGTON, MA (US)

(72) Inventors: ROBERT J. NICK, PEPPERELL, MA (US); JONATHAN S. STECKEL, SARATOGA, CA (US)

(21) Appl. No.: 15/159,424

(22) Filed: May 19, 2016

Related U.S. Application Data
(63) Continuation of application No. PCT/US2014/066457, filed on Nov. 19, 2014.
(60) Provisional application No. 61/906,382, filed on Nov. 19, 2013.

(51) Int. Cl. H01L 33/50; H01L 33/64

(52) U.S. Cl. CPC H01L 33/507; H01L 33/64

(57) ABSTRACT

A light emitting device including a light emitting element having a light emitting surface and an optical component comprising an optical material comprising quantum dots sealed within an optically transparent structural member, the optical component being coupled to the light emitting element by a thermally conductive member is disclosed. A light emitting device including a light emitting element having a light emitting surface and an optical component comprising an optical material comprising quantum dots sealed within a structural member comprising single crystal sapphire, the optical component being coupled to the light emitting element by a thermally conductive member, is also disclosed.

This application is a continuation of International Application No. PCT/US2014/066457, filed 19 Nov. 2014, which was published in the English language as International Publication No. WO 2015/077369 on 28 May 2015, which International Application claims priority to U.S. Provisional Patent Application No. 61/906,382, filed on 19 Nov. 2013. Each of the foregoing is hereby incorporated herein by reference in its entirety for all purposes.

### TECHNICAL FIELD OF THE INVENTION

The present invention relates to the field of light emitting devices, and more particularly to light emitting devices including quantum dots.

### SUMMARY OF THE INVENTION

The present invention relates to light emitting device including quantum dots.

In accordance with one aspect of the present invention there is provided a light emitting device including a light emitting element having a light emitting surface and an optical component comprising an optical material comprising quantum dots sealed within an optically transparent structural member, the optical component being coupled to the light emitting element by a thermally conductive member.

The optically transparent structural member can comprise glass. The optically transparent structural member can comprise single crystal sapphire.

The thermally conductive member can comprise a layer comprising an optically clear thermal transfer gel.

The thermally conductive member can comprise a structural element included in the light emitting device to which the optical component is directly or indirectly attached in positioning the optical component relative to the light emitting element, the structural member comprising a thermally conductive plastic. There may be a gap between the light emitting element and optical component. In such case, the gap can be at least partially filled with a gas. If there is a gap, the gap can be at least partially filled with a thermal transfer gel.

Preferably the optical component is thermally coupled to the thermally conductive member.

Preferably the quantum dots are hermetically sealed within the optical component.

In accordance with another aspect of the present invention, there is provided a light emitting device including a light emitting element having a light emitting surface and an optical component comprising an optical material comprising quantum dots sealed within a structural member comprising glass, the optical component being coupled to the light emitting element by a thermally conductive member.

Preferably the optical component is thermally coupled to the thermally conductive member.

Preferably the quantum dots are hermetically sealed within the optical component.

In accordance with another aspect of the present invention, there is provided a light emitting device including a light emitting element having a light emitting surface and an optical component comprising an optical material comprising quantum dots sealed within a structural member comprising single crystal sapphire, the optical component being coupled to the light emitting element by a thermally conductive member.

Preferably the optical component is thermally coupled to the thermally conductive member.

Preferably the quantum dots are hermetically sealed within the optical component.

The foregoing, and other aspects described herein, all constitute embodiments of the present invention.

It should be appreciated by those persons having ordinary skill in the art(s) to which the present invention relates that any of the features described herein in respect of any particular aspect and/or embodiment of the present invention can be combined with one or more of any of the other features of any other aspects and/or embodiments of the present invention described herein, with modifications as appropriate to ensure compatibility of the combinations. Such combinations are considered to be part of the present invention contemplated by this disclosure.

It is to be understood that both the foregoing general description and the following detailed description are exemplary and explanatory only and are not restrictive of the invention as claimed.

Other embodiments will be apparent to those skilled in the art from consideration of the description and drawings, from the claims, and from practice of the invention disclosed herein.

### BRIEF DESCRIPTION OF THE DRAWINGS

In the drawings,

FIG. 1 is a schematic drawing of an example of a first embodiment of the invention.

FIG. 2 is a schematic drawing of an example of a second embodiment of the invention.

FIG. 3 is a schematic drawing of an example of a third embodiment of the invention.

FIG. 4 is a schematic drawing of an example of a fourth embodiment of the invention.

FIG. 5 is a schematic drawing of an example of a fifth embodiment of the invention.

The attached figures are simplified representations presented for purposes of illustration only; the actual structures may differ in numerous respects, particularly including the relative scale of the articles depicted and aspects thereof.

For a better understanding to the present invention, together with other advantages and capabilities thereof, reference is made to the following disclosure and appended claims in connection with the above-described drawings.

### DETAILED DESCRIPTION OF THE INVENTION

Various aspects and embodiments of the present inventions will be further described in the following detailed description.

In accordance with one aspect of the present invention there is provided a light emitting device including a light emitting element having a light emitting surface and an optical component comprising an optical material comprising quantum dots sealed within an optically transparent structural member, the optical component being coupled to the light emitting element by a thermally conductive member.

The optically transparent structural member can comprise glass. The optically transparent structural member can comprise single crystal sapphire.

In accordance with one aspect, an optical component is directly or indirectly coupled to a light emitting element of a light emitting device by a thermally conductive member comprising a thermal transfer gel.

Preferably the optical component is thermally coupled to the thermally conductive member.

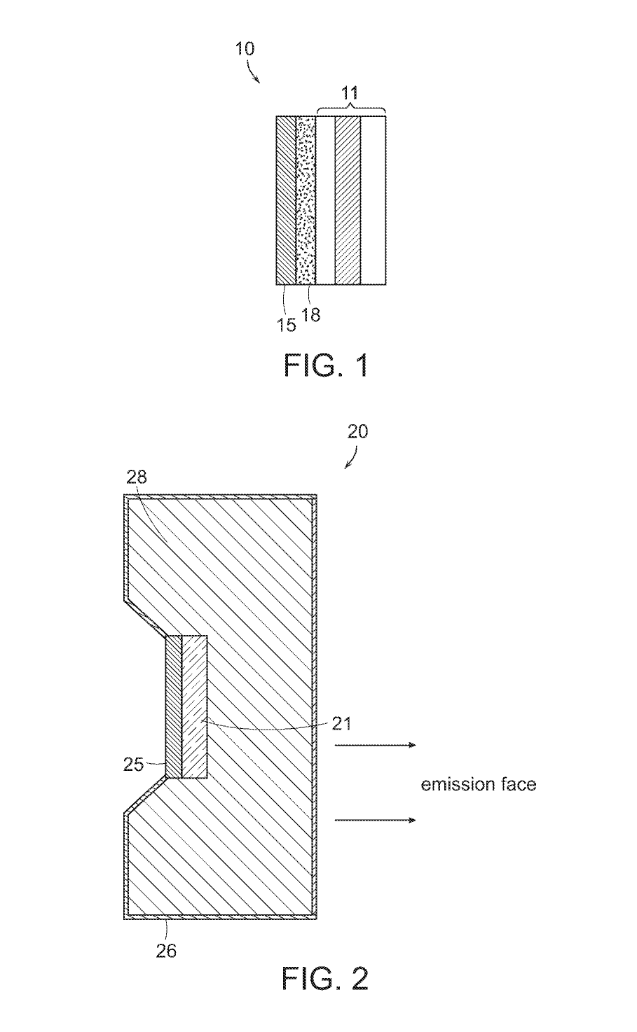

FIG. 1 schematically depicts, in cross section, an example of an embodiment of a light emitting device of the present invention. In FIG. 1, the depicted light emitting device 10 includes an optical component 11 including an optical material comprising quantum dots sealed within an optically transparent structural member (the depicted optical component comprising a layer including an optical material comprising quantum dots sealed between planar glass substrates) coupled to a light emitting element 15 (shown as a semiconductor chip or die). The light emitting element 15 is further heat sinked to a circuit board or other heat sinking component (not shown)). In the depicted example, the thermally conductive member is shown as a layer of thermally conductive gel that couples the optical component and the light emitting element. Preferably the thermally conductive gel is optically clear in the spectral range of the light emitted by the die (typically in the 450 nm region of the spectrum) in order to not diminish the light pumping efficiency of the die face into the optical component. The further inclusion of a layer of a thermally conductive gel around at least a portion, and preferably all, of the other outer surfaces of the optical component would further facilitate the transfer of heat from the optical component, through the thermal transfer gel, and into to die to be dissipated by the existing die heat sink (not shown).

FIG. 2 schematically depicts, in cross section, an example of another embodiment of a light emitting device of the present invention. In FIG. 2, the depicted light emitting device 20 includes an optical component 21 including an optical material comprising quantum dots sealed within an optically transparent structural member (the depicted optical component comprising a layer including an optical material comprising quantum dots sealed between planar glass substrates) adjacent a light emitting element (shown as a die) 25, with both the light emitting element and optical component being positioned within the side walls of a housing 26. In the depicted example, a thermally conductive member 28 comprising a thermally conductive gel is disposed between the side walls of the housing and the sides of the arrangement including the optical component and light emitting element. Optionally, the thermally conductive member comprising a thermally conductive gel can be further disposed over at least the upper surface of the optical component and can further extend to the housing side walls of the housing, and optionally further fill the remainder of the housing space above the optical component. Preferably the thermally conductive gel is optically clear in the spectral range of the light emitted by the die (typically in the 450 nm region of the spectrum) in order to not diminish the light pumping efficiency of the die face into the optical component. Optionally, the housing comprises a thermally conductive member comprising a thermally conductive plastic.

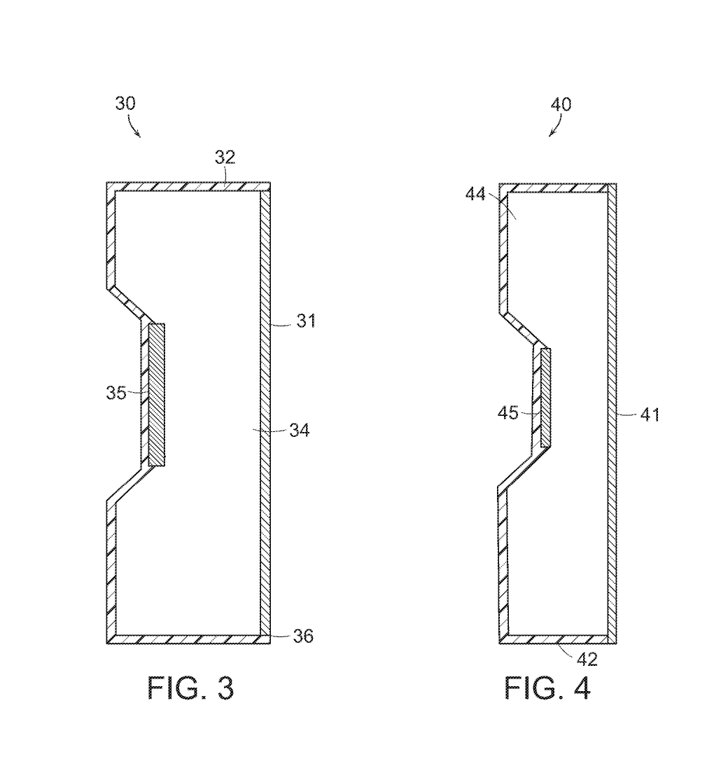

FIG. 3 schematically depicts, in cross section, an example of another embodiment of a light emitting device of the present invention. In FIG. 3, the depicted light emitting device 30 includes a thermally conductive member 32 (e.g., a housing (e.g., housing cup) for the light emitting element) comprising a thermally conductive plastic. A light emitting element 35 (e.g., a semiconductor or chip) is positioned at the internal bottom of the depicted housing and an optical component 31 is attached at the top of the housing between the housing side walls, leaving a gap 34 between the top surface of the light emitting element and the surface of the optical component facing the light emitting element. In the depicted example, the optical component is fastened to the side walls by a thermal adhesive 36 at the interface between the side walls and the side or perimeter edge of the optical component. (An optical component can comprise a layer including an optical material comprising quantum dots sealed between planar glass substrates.) Preferably the optical component has a shape and size (in the planar dimensions) selected based on the internal dimensions of the top of the housing in order to form a closed structure when attached to the housing. Optionally, the gap between the light emitting element and the optical component can be at least partially or fully filled with a thermally conductive gel. Alternatively, the gap can be an air gap. Preferably, if included, the thermally conductive gel is optically clear in the spectral range of the light emitted by the die (typically in the 450 nm region of the spectrum) in order to not diminish the light pumping efficiency of the die face into the optical component. In another design, the optical component can be recessed below the top edge of the housing. When the thermally conductive member is included in the housing, the entire housing can comprise a thermally conductive plastic or only a portion thereof. Other thermally conductive materials that can be included in a thermally conductive member include metals and ceramics.

FIG. 4 schematically depicts, in cross section, an example of another embodiment of a light emitting device of the present invention. In FIG. 4, the depicted light emitting device 40 includes a thermally conductive member 42 (e.g., the housing for the light emitting element) comprising a thermally conductive plastic. A light emitting element 45 (e.g., a semiconductor or chip) is positioned on the internal bottom surface of the depicted housing and an optical component 41 is attached at the top of the housing, overlapping or covering the top edges of the side walls, leaving a gap 44 between the light emitting element and the face of the optical component facing the light emitting element. In the depicted example, the optical component is fastened to the side walls by a thermal adhesive. (An optical component can comprise a layer including an optical material comprising quantum dots sealed between planar glass substrates.) Preferably the optical component has a shape and size selected based on the external dimensions of the top of the housing in order to form a closed structure when attached to the housing, with the optical component overlapping at least a portion of the top edges of the side walls of the housing. Optionally, the gap between the light emitting element and the optical component can be at least partially or fully filled with a thermally conductive gel. Alternatively, the gap can be an air gap. Preferably, if included, the thermally conductive gel is optically clear in the spectral range of the light emitted by the die (typically in the 450 nm region of the spectrum) in order to not diminish the light pumping efficiency of the die face into the optical component. In another design, the optical component can be recessed below the top edge of the housing. When the thermally conductive member is included in the housing, the entire housing can comprise a thermally conductive plastic or only a portion thereof. Other thermally conductive materials that can be included in a thermally conductive member include metals and ceramics.

In the configurations shown by the example depicted in FIGS. 3 and 4, with the optical component recessed into the housing (FIG. 3) or with the optical component overlapping at least a portion of the top edge of the housing (FIG. 4), there would be heat transfer from the optical component to the thermally conductive housing through its contact point with the thermally conductive member (e.g. the housing) to dissipate heat from the quantum dots included the optical material included in the optical component.

Examples of thermally conductive plastics for use in the present invention include, but are not limited to, CoolPoly® thermally conductive plastics available from Cool Polymers, Inc, including, but not limited to, those for use in encapsulating semiconductor and electronic devices, including, but not limited to, thermally conductive injection molding grade thermoplastics. In certain embodiments, the thermally conductive plastic can comprise CoolPoly D5112. Other suitable thermally conductive plastics can be ascertained by the skilled artisan.

Examples of thermally conductive gels (or pastes) for use in the present invention include , but are not limited to, optically clear SmartGel® silicone-based optical couplants available from Nye Optical Products, Fairhaven, Mass. Other suitable thermally conductive gels can be ascertained by the skilled artisan.

As mentioned above, the gap between the optical component and the lighting element in the configurations shown in FIGS. 3 and 4 can be at least partially or completely filled with gas or with the a thermally conductive gel described elsewhere herein.

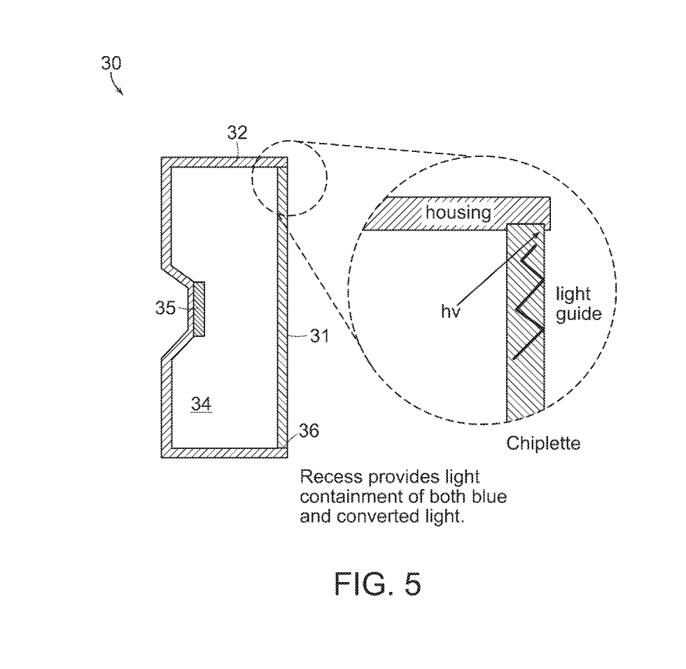

In the example depicted in FIG. 3, wherein the optical component is recessed and secured to the internal surface of the housing side walls, leakage of unconverted light from the light emitting element (e.g., typically blue light) outside of the LED housing would be prevented since the optical component edge would terminate in the wall of the housing (FIG. 5). (An optical component is also referred to in FIG. 5 as a chiplette.) In addition, as depicted in the expanded view of the interface of the optical component and housing side wall in FIG. 5, converted light from the optical component, which could light-pipe across the optical component, would be reflected back rather than be lost out of the edge of the optic.

In the above examples, the thermal adhesive can comprise a thermally conductive gel or paste described elsewhere herein.

Thermal management may also be improved by heat dissipation through a face of the optical component. For instance, in switching a the material of construction of a glass structural element of an optical component to single crystal sapphire, the thermal conductivity of the element will increase from 1.14 to 41 W/m-K. Examples of single crystal sapphire for such use are available from Kyocera. Sapphire on glass can also be used as a planar structural element of an optical component. Use of quartz rather than borosilicate can also increase optical transmission by as much as 3%, resulting in lower absorption and heat generation.

An optical material includes quantum dots.

Quantum dots (which may also be referred to herein as semiconductor nanocrystals or inorganic semiconductor nanocrystals) are nanometer sized particles that can have optical properties arising from quantum confinement. The particular composition(s), structure, and/or size of a quantum dot can be selected to achieve the desired wavelength of light to be emitted from the quantum dot upon stimulation with a particular excitation source. In essence, quantum dots may be tuned to emit light across the visible spectrum by changing their size.

Quantum dots can have an average particle size in a range from about 1 to about 1000 nanometers (nm), and preferably in a range from about 1 to about 100 nm. In certain embodiments, quantum dots have an average particle size in a range from about 1 to about 20 nm (e.g., such as about 5, 6, 7, 8, 9, 10, 11, 12, 13, 14, 15, 16, 17, 18, 19, or 20 nm). In certain embodiments, quantum dots have an average particle size in a range from about 1 to about 10 nm. Quantum dots can have an average diameter less than about 150 Angstroms (Å). In certain embodiments, quantum dots having an average diameter in a range from about 12 to about 150 Å can be particularly desirable. However, depending upon the composition, structure, and desired emission wavelength of the quantum dot, the average diameter may be outside of these ranges.

Preferably, a quantum dot comprises a semiconductor nanocrystal. In certain embodiments, a semiconductor nanocrystal has an average particle size in a range from about 1 to about 20 nm, and preferably from about 1 to about 10 nm. However, depending upon the composition, structure, and desired emission wavelength of the quantum dot, the average diameter may be outside of these ranges.

A quantum dot can comprise one or more semiconductor materials.

Examples of semiconductor materials that can be included in a quantum dot (including, e.g., semiconductor nanocrystal) include, but are not limited to, a Group IV element, a Group II-VI compound, a Group II-V compound, a Group III-VI compound, a Group III-V compound, a Group IV-VI compound, a Group compound, a Group II-IV-VI compound, a Group II-IV-V compound, an alloy including any of the foregoing, and/or a mixture including any of the foregoing, including ternary and quaternary mixtures or alloys. A non-limiting list of examples include ZnO, ZnS, ZnSe, ZnTe, CdO, CdS, CdSe, CdTe, MgS, MgSe, GaAs, GaN, GaP, GaSe, GaSb, HgO, HgS, HgSe, HgTe, InAs, InN, InP, InSb, AlAs, AN, AlP, AlSb, TlN, TlP, TlAs, TlSb, PbO, PbS, PbSe, PbTe, Ge, Si, an alloy including any of the foregoing, and/or a mixture including any of the foregoing, including ternary and quaternary mixtures or alloys.

In certain embodiments, quantum dots can comprise a core comprising one or more semiconductor materials and a shell comprising one or more semiconductor materials, wherein the shell is disposed over at least a portion, and preferably all, of the outer surface of the core. A quantum dot including a core and shell is also referred to as a “core/shell” structure.

For example, a quantum dot can include a core having the formula MX, where M is cadmium, zinc, magnesium, mercury, aluminum, gallium, indium, thallium, or mixtures thereof, and X is oxygen, sulfur, selenium, tellurium, nitrogen, phosphorus, arsenic, antimony, or mixtures thereof. Examples of materials suitable for use as quantum dot cores include, but are not limited to, ZnO, ZnS, ZnSe, ZnTe, CdO, CdS, CdSe, CdTe, MgS, MgSe, GaAs, GaN, GaP, GaSe, GaSb, HgO, HgS, HgSe, HgTe, InAs, InN, InP, InSb, AlAs, AN, AlP, AlSb, TlN, TlP, TlAs, TlSb, PbO, PbS, PbSe, PbTe, Ge, Si, an alloy including any of the foregoing, and/or a mixture including any of the foregoing, including ternary and quaternary mixtures or alloys.

A shell can be a semiconductor material having a composition that is the same as or different from the composition of the core. The shell can comprise an overcoat including one or more semiconductor materials on a surface of the core. Examples of semiconductor materials that can be included in a shell include, but are not limited to, a Group IV element, a Group II-VI compound, a Group II-V compound, a Group III-VI compound, a Group III-V compound, a Group IV-VI compound, a Group compound, a Group II-IV-VI compound, a Group II-IV-V compound, alloys including any of the foregoing, and/or mixtures including any of the foregoing, including ternary and quaternary mixtures or alloys. Examples include, but are not limited to, ZnO, ZnS, ZnSe, ZnTe, CdO, CdS, CdSe, CdTe, MgS, MgSe, GaAs, GaN, GaP, GaSe, GaSb, HgO, HgS, HgSe, HgTe, InAs, InN, InP, InSb, AlAs, AN, AlP, AlSb, TlN, TlP, TlAs, TlSb, PbO, PbS, PbSe, PbTe, Ge, Si, an alloy including any of the foregoing, and/or a mixture including any of the foregoing. For example, ZnS, ZnSe or CdS overcoatings can be grown on CdSe or CdTe semiconductor nanocrystals.

In a core/shell quantum dot, the shell or overcoating may comprise one or more layers. The overcoating can comprise at least one semiconductor material which is the same as or different from the composition of the core. Preferably, the overcoating has a thickness from about one to about ten monolayers. An overcoating can also have a thickness greater than ten monolayers. In certain embodiments, more than one overcoating can be included on a core.

In certain embodiments, the surrounding “shell” material can have a band gap greater than the band gap of the core material. In certain other embodiments, the surrounding shell material can have a band gap less than the band gap of the core material.

In certain embodiments, the shell can be chosen so as to have an atomic spacing close to that of the “core” substrate. In certain other embodiments, the shell and core materials can have the same crystal structure.

Examples of quantum dot (e.g., semiconductor nanocrystal) (core)shell materials include, without limitation: red (e.g., (CdSe)CdZnS (core)shell), green (e.g., (CdZnSe)CdZnS (core)shell, etc.), and blue (e.g., (CdS)CdZnS (core)shell.

Quantum dots can have various shapes, including, but not limited to, sphere, rod, disk, other shapes, and mixtures of various shaped particles.

One example of a method of manufacturing a quantum dot (including, for example, but not limited to, a semiconductor nanocrystal) is a colloidal growth process. Resulting quantum dots are members of a population of quantum dots. As a result of the discrete nucleation and controlled growth, the population of quantum dots that can be obtained has a narrow, monodisperse distribution of diameters. The monodisperse distribution of diameters can also be referred to as a size. Preferably, a monodisperse population of particles includes a population of particles wherein at least about 60% of the particles in the population fall within a specified particle size range. A population of monodisperse particles preferably deviate less than 15% rms (root-mean-square) in diameter and more preferably less than 10% rms and most preferably less than 5%.

An example of an overcoating process is described, for example, in U.S. Pat. No. 6,322,901. By adjusting the temperature of the reaction mixture during overcoating and monitoring the absorption spectrum of the core, overcoated materials having high emission quantum efficiencies and narrow size distributions can be obtained.

The narrow size distribution of the quantum dots or semiconductor nanocrystals allows the possibility of light emission in narrow spectral widths. Monodisperse semiconductor nanocrystals have been described in detail in Murray et al. (J. Am. Chem. Soc., 115:8706 (1993)) which is hereby incorporated herein by reference in its entirety.

Semiconductor nanocrystals and other types of quantum dots preferably have ligands attached thereto. According to one aspect, quantum dots within the scope of the present invention include green CdSe quantum dots having oleic acid ligands and red CdSe quantum dots having oleic acid ligands. Alternatively, or in addition, octadecylphosphonic acid (“ODPA”) ligands may be used instead of oleic acid ligands. The ligands promote solubility of the quantum dots in the polymerizable composition which allows higher loadings without agglomeration which can lead to red shifting.

Ligands can be derived from a coordinating solvent that may be included in the reaction mixture during the growth process.

Ligands can be added to the reaction mixture.

Ligands can be derived from a reagent or precursor included in the reaction mixture for synthesizing the quantum dots.

In certain embodiments, quantum dots can include more than one type of ligand attached to an outer surface.

A quantum dot surface that includes ligands derived from the growth process or otherwise can be modified by repeated exposure to an excess of a competing ligand group (including, e.g., but not limited to, coordinating group) to form an overlayer. For example, a dispersion of the capped quantum dots can be treated with a coordinating organic compound, such as pyridine, to produce crystallites which disperse readily in pyridine, methanol, and aromatics but no longer disperse in aliphatic solvents. Such a surface exchange process can be carried out with any compound capable of coordinating to or bonding with the outer surface of the nanoparticle, including, for example, but not limited to, phosphines, thiols, amines and phosphates.

Examples of additional ligands include fatty acid ligands, long chain fatty acid ligands, alkyl phosphines, alkyl phosphine oxides, alkyl phosphonic acids, or alkyl phosphinic acids, pyridines, furans, and amines More specific examples include, but are not limited to, pyridine, tri-n-octyl phosphine (TOP), tri-n-octyl phosphine oxide (TOPO), tris-hydroxylpropylphosphine (tHPP) and octadecylphosphonic acid (“ODPA”). Technical grade TOPO can be used.

Suitable coordinating ligands can be purchased commercially or prepared by ordinary synthetic organic techniques.

The emission from a quantum dot capable of emitting light can be a narrow Gaussian emission band that can be tuned through the complete wavelength range of the ultraviolet, visible, or infra-red regions of the spectrum by varying the size of the quantum dot, the composition of the quantum dot, or both. For example, a semiconductor nanocrystal comprising CdSe can be tuned in the visible region; a semiconductor nanocrystal comprising InAs can be tuned in the infra-red region. The narrow size distribution of a population of quantum dots capable of emitting light can result in emission of light in a narrow spectral range. The population can be monodisperse preferably exhibits less than a 15% rms (root-mean-square) deviation in diameter of such quantum dots, more preferably less than 10%, most preferably less than 5%. Spectral emissions in a narrow range of no greater than about 75 nm, preferably no greater than about 60 nm, more preferably no greater than about 40 nm, and most preferably no greater than about 30 nm full width at half max (FWHM) for such quantum dots that emit in the visible can be observed. IR-emitting quantum dots can have a FWHM of no greater than 150 nm, or no greater than 100 nm. Expressed in terms of the energy of the emission, the emission can have a FWHM of no greater than 0.05 eV, or no greater than 0.03 eV. The breadth of the emission decreases as the dispersity of the light-emitting quantum dot diameters decreases.

Quantum dots can have emission quantum efficiencies such as greater than 10%, 20%, 30%, 40%, 50%, 60%, 70%, 80%, or 90%.

The narrow FWHM of quantum dots can result in saturated color emission. The broadly tunable, saturated color emission over the entire visible spectrum of a single material system is unmatched by any class of organic chromophores (see, for example, Dabbousi et al., J. Phys. Chem. 101, 9463 (1997), which is incorporated by reference in its entirety). A monodisperse population of quantum dots will emit light spanning a narrow range of wavelengths.

Useful quantum dots according to the present invention include those that emit wavelengths characteristic of red light. In certain preferred embodiments, quantum dots capable of emitting red light emit light having a peak center wavelength in a range from about 615 nm to about 635 nm, and any wavelength or range in between whether overlapping or not. For example, the quantum dots can be capable or emitting red light having a peak center wavelength of about 635 nm, about 630 nm, of about 625 nm, of about 620 nm, of about 615 nm.

Useful quantum dots according to the present invention also include those that emit wavelength characteristic of green light. In certain preferred embodiments, quantum dots capable of emitting green light emit light having a peak center wavelength in a range from about 520 nm to about 545 nm, and any wavelength or range in between whether overlapping or not. For example, the quantum dots can be capable or emitting green light having a peak center wavelength of about 520 nm, of about 525 nm, of about 535 nm, of about 540 nm or of about 540 nm.

The narrow emission profile of quantum dots of the present invention allows the tuning of the quantum dots and mixtures of quantum dots to emit saturated colors thereby increasing color gamut and power efficiency beyond that of conventional LED lighting displays. According to one aspect, green quantum dots designed to emit a predominant wavelength of, for example, about 523 nm and having an emission profile with a FWHM of about, for example, 37 nm are combined, mixed or otherwise used in combination with red quantum dots designed to emit a predominant wavelength of about, for example, 617 nm and having an emission profile with a FWHM of about, for example 32 nm. Such combinations can be stimulated by blue light to create trichromatic white light.

An optical material within the scope of the invention can further include a host material. A host material may be present in the optical material in an amount from about 50 weight percent and about 99.5 weight percent, and any weight percent in between whether overlapping or not. In certain embodiment, a host material may be present in an amount from about 80 to about 99.5 weight percent. Examples of specific useful host materials include, but are not limited to, polymers, oligomers, monomers, resins, binders, glasses, metal oxides, and other nonpolymeric materials. Preferred host materials include polymeric and non-polymeric materials that are at least partially transparent, and preferably fully transparent, to preselected wavelengths of light. In certain embodiments, the preselected wavelengths can include wavelengths of light in the visible (e.g., 400-700 nm) region of the electromagnetic spectrum. Preferred host materials include cross-linked polymers and solvent-cast polymers. Examples of other preferred host materials include, but are not limited to, glass or a transparent resin. In particular, a resin such as a non-curable resin, heat-curable resin, or photocurable resin is suitably used from the viewpoint of processability. Specific examples of such a resin, in the form of either an oligomer or a polymer, include, but are not limited to, a melamine resin, a phenol resin, an alkyl resin, an epoxy resin, a polyurethane resin, a maleic resin, a polyamide resin, polymethyl methacrylate, polyacrylate, polycarbonate, polyvinyl alcohol, polyvinylpyrrolidone, hydroxyethylcellulose, carboxymethylcellulose, copolymers containing monomers or oligomers forming these resins, and the like. Other suitable host materials can be identified by persons of ordinary skill in the relevant art.

Host materials can also comprise silicone materials. Suitable host materials comprising silicone materials can be identified by persons of ordinary skill in the relevant art.

In certain embodiments and aspects of the inventions contemplated by this invention, a host material comprises a photocurable resin. A photocurable resin may be a preferred host material in certain embodiments, e.g., in embodiments in which the composition is to be patterned. As a photo-curable resin, a photo-polymerizable resin such as an acrylic acid or methacrylic acid based resin containing a reactive vinyl group, a photo-crosslinkable resin which generally contains a photo-sensitizer, such as polyvinyl cinnamate, benzophenone, or the like may be used. A heat-curable resin may be used when the photo-sensitizer is not used. These resins may be used individually or in combination of two or more.

In certain embodiments, a host material can comprise a solvent-cast resin. A polymer such as a polyurethane resin, a maleic resin, a polyamide resin, polymethyl methacrylate, polyacrylate, polycarbonate, polyvinyl alcohol, polyvinylpyrrolidone, hydroxyethylcellulose, carboxymethylcellulose, copolymers containing monomers or oligomers forming these resins, and the like can be dissolved in solvents known to those skilled in the art. Upon evaporation of the solvent, the resin forms a solid host material for the semiconductor nanoparticles.

In certain embodiments, acrylate monomers and/or acrylate oligomers which are commercially available from Radcure and Sartomer can be preferred.

Optical material comprises a host material in which the quantum dots are dispersed can be preferred.

Quantum dots can be encapsulated. Nonlimiting examples of encapsulation materials, related methods, and other information that may be useful are described in International Application No. PCT/US2009/01372 of Linton, filed 4 Mar. 2009 entitled “Particles Including Nanoparticles, Uses Thereof, And Methods” and U.S. Patent Application No. 61/240,932 of Nick et al., filed 9 Sep. 2009 entitled “Particles Including Nanoparticles, Uses Thereof, And Methods”, each of the foregoing being hereby incorporated herein by reference in its entirety.

The total amount of quantum dots included in an optical material that includes a host material is preferably in a range from about 0.05 weight percent to about 10 weight percent, and more preferably in a range from about 0.05 weight percent to about 5 weight percent, and more preferably from about 0.1 weight percent to about 5 weight percent and any value or range in between whether overlapping or not. The amount of quantum dots included in an optical material can vary within such range depending upon the application and the form in which the quantum dots are included, which can be chosen based on the particular end application.

The ratio of quantum dots used in an optical material is determined by the emission peaks of the quantum dots used. For example, when quantum dots capable of emitting green light having a peak center wavelength in a range from about 514 nm to about 545 nm, and any wavelength in between whether overlapping or not, and quantum dots capable of emitting red light having a peak center wavelength in a range from about 615 nm to about 640 nm, and any wavelength in between whether overlapping or not, are used in an optical material, the ratio of the weight percent green-emitting quantum dots to the weight percent of red-emitting quantum dots can be in a range from about 12:1 to about 1:1, and any ratio in between whether overlapping or not.

The above ratio of weight percent green-emitting quantum dots to weight percent red-emitting quantum dots in an optical material can alternatively be presented as a molar ratio. For example, the above weight percent ratio of green to red quantum dots range can correspond to a green to red quantum dot molar ratio in a range from about 24.75 to 1 to about 5.5 to 1, and any ratio in between whether overlapping or not.

The ratio of the blue to green to red light output intensity in white trichromatic light emitted by a quantum dot containing light emitting device including blue-emitting solid state inorganic semiconductor light emitting devices (having blue light with a peak center wavelength in a range from about 450 nm to about 460 nm, and any wavelength in between whether overlapping or not), and an optical material including mixtures of green-emitting quantum dots and red-emitting quantum dots can vary.

Scatterers, also referred to as scattering agents, may be included in an optical material, for example, in an amount of between about 0.01 weight percent and about 1 weight percent. Amounts of scatterers outside such range may also be useful. Examples of light scatterers (also referred to herein as scatterers or light scattering particles) that can be used in the embodiments and aspects of the inventions described herein, include, without limitation, metal or metal oxide particles, air bubbles, and glass and polymeric beads (solid or hollow). Other light scatterers can be readily identified by those of ordinary skill in the art. In certain embodiments, scatterers have a spherical shape. Preferred examples of scattering particles include, but are not limited to, TiO₂, SiO₂, BaTiO₃, BaSO₄, and ZnO. Particles of other materials that are non-reactive with the host material and that can increase the absorption pathlength of the excitation light in the host material can be used. In certain embodiments, light scatterers may have a high index of refraction (e.g., TiO₂, BaSO₄, etc) or a low index of refraction (gas bubbles).

Selection of the size and size distribution of the scatterers is readily determinable by those of ordinary skill in the art. The size and size distribution can be based upon the refractive index mismatch of the scattering particle and the host material in which the light scatterers are to be dispersed, and the preselected wavelength(s) to be scattered according to Rayleigh scattering theory. The surface of the scattering particle may further be treated to improve dispersability and stability in the host material. In one embodiment, the scattering particle comprises TiO₂ (R902+ from DuPont) of 0.2 μm particle size, in a concentration in a range from about 0.01 to about 1% by weight.

Examples of thixotropes which may be included in an optical material (thixotropes also being referred to as rheology modifiers) include, but are not limited to, fumed metal oxides (e.g., fumed silica which can be surface treated or untreated (such as Cab-O-Sil™ fumed silica products available from Cabot Corporation)), fumed metal oxide gels (e.g., a silica gel). An optical material can include an amount of thixotrope in a range from about 0.5 to about 12 weight percent or from about 5 to about 12 weight percent. Other amounts outside the range may also be determined to be useful or desirable.

An optical material can include two or more different types of quantum dots that emit at different predetermined wavelengths, the different types of quantum dots can be included in one or more different optical materials.

In certain embodiments including two or more different optical materials, such different optical materials can, for example, be included as separate layers of a layered arrangement

An optical component can further include a structural member that contains the optical material. Such structural member can have a variety of different shapes or configurations. For example, it can be planar, hollow, circular, square, rectangular, oval, spherical, cylindrical, or any other shape or configuration that is appropriate based on the intended end-use application and design. An example of a common structural component is a sandwiched arrangement of planar substrates.

Preferably the structural member is optically transparent. A structural member can comprise glass. A structural member can comprise single crystal sapphire. A structural member can comprise sapphire on glass.

Preferably, the optical material is sealed within the structural member.

For example, the optical material can be sandwiched between opposing substrates that are sealed together by a seal. In certain embodiments, one or both of the substrates comprise glass.

The seal can comprise an edge or perimeter seal. The seal can comprise a barrier material. The seal can comprise a barrier to oxygen and/or water. The seal can be substantially impervious to water and/or oxygen. Preferably, the seal comprises an oxygen barrier.

An hermetic seal is preferred to avoid oxygen being within the optical component. For example, an optical material can be disposed between opposing glass plates and/or sheets with the perimeter edges being hermetically sealed.

In another example, an optical component can comprise an optical material included within a structural member. For example, the optical material can be included in a hollow or cavity portion of a structural member that can be open at either or both ends. Preferably open end(s) of the member are hermetically sealed after the composition is included therein. Examples of sealing techniques include covering the open end with a glass adhering metal such as a glass adhering solder or other glass adhering material, melting the open end by heating the glass above the melting point of the glass and pinching the walls together to close the opening to form a molten glass hermetic seal, glass frit seals, etc.

Other suitable techniques can be used for sealing the optical component.

A structural member is preferably optically transparent to permit light to pass into and/or out of the optical material that it may encapsulate.

The configuration and dimensions of an optical component can be selected based on the intended end-use application and design.

An optical component comprising a structural member in which the composition is hermetically contained can be preferred

An optical component can further include one or more barrier materials which can be selected to protect the optical material from environmental effects (e.g., oxygen and/or water) which may be detrimental for a given end-use application.

Additional information that may be useful in connection with the present disclosure and the inventions described herein is included in International Application No. PCT/US2009/002796 of Coe-Sullivan et al, filed 6 May 2009, entitled “Optical Components, Systems Including An Optical Component, And Devices”; International Application No. PCT/US2009/002789 of Coe-Sullivan et al, filed 6 May 2009, entitled : “Solid State Lighting Devices Including Quantum Confined Semiconductor Nanoparticles, An Optical Component For A Solid State Light Device, And Methods”; International Application No. PCT/US2010/32859 of Modi et al, filed 28 Apr. 2010 entitled “Optical Materials, Optical Components, And Methods”; International Application No. PCT/US2010/032799 of Modi et al, filed 28 Apr. 2010 entitled “Optical Materials, Optical Components, Devices, And Methods”; International Application No. PCT/US2011/047284 of Sadasivan et al, filed 10 Aug. 2011 entitled “Quantum Dot Based Lighting”; International Application No. PCT/US2008/007901 of Linton et al, filed 25 Jun. 2008 entitled “Compositions And Methods Including Depositing Nanomaterial”; U.S. patent application Ser. No. 12/283,609 of Coe-Sullivan et al, filed 12 Sep. 2008 entitled “Compositions, Optical Component, System Including An Optical Component, Devices, And Other Products”; International Application No. PCT/US2008/10651 of Breen et al, filed 12 Sep. 2008 entitled “Functionalized Nanoparticles And Method”; U.S. Pat. No. 6,600,175 of Baretz, et al., issued Jul. 29, 2003, entitled “Solid State White Light Emitter And Display Using Same”; and U.S. Pat. No. 6,608,332 of Shimizu, et al., issued Aug. 19, 2003, entitled “Light Emitting Device and Display”; and U.S. patent application Ser. No. 13/762,354 of Nick, et al., filed 7 Feb. 2013, entitled “Methods of Making Components Including Quantum Dots, Methods, and Products”; each of the foregoing being hereby incorporated herein by reference in its entirety.

As used herein, the singular forms “a”, “an” and “the” include plural unless the context clearly dictates otherwise. Thus, for example, reference to an emissive material includes reference to one or more of such materials.

Applicants specifically incorporate the entire contents of all cited references in this disclosure. Further, when an amount, concentration, or other value or parameter is given as either a range, preferred range, or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

Other embodiments of the present invention will be apparent to those skilled in the art from consideration of the present specification and practice of the present invention disclosed herein. It is intended that the present specification and examples be considered as exemplary only with a true scope and spirit of the invention being indicated by the following claims and equivalents thereof.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. A light emitting device including a light emitting element having a light emitting surface and an optical component comprising an optical material comprising quantum dots sealed within a structure comprising glass, the optical component being coupled to the light emitting element by a thermally conductive member.

2. A light emitting device in accordance with claim 1 wherein the thermally conductive member comprises a layer comprising a thermal transfer gel.

3. A light emitting device in accordance with claim 2 wherein the thermally conductive member comprises a layer comprising an optically clear thermal transfer gel.

4. A light emitting device in accordance with claim 2 wherein the layer is between the light emitting element and the optical component.

5. A light emitting device in accordance with claim 2 wherein the layer covers a surface of the optical component opposite a surface of the optical component facing the light emitting surface of the light emitting element.

6. A light emitting device in accordance with claim 3 wherein a second layer comprising the thermal transfer gel covers a surface of the optical component opposite a surface of the optical component facing the light emitting surface of the light emitting element.

7. A light emitting device in accordance with claim 2 wherein the light emitting device further includes a substrate having a surface on which the light emitting element is mounted, wherein at least a portion of the surface of the substrate around the perimeter of the light emitting element is not covered by the light emitting element, and wherein the optical component is disposed over the light emitting surface of the light emitting element, and the layer covers a surface of the optical component opposite a surface of the optical component facing the light emitting surface of the light emitting element and at least a portion of the substrate surface not covered by the light emitting element.

8. A light emitting device in accordance with claim 1 wherein the thermally conductive member comprises a structural element included in the light emitting device to which the optical component is directly or indirectly attached in positioning the optical component relative to the light emitting element, the structural member comprising a thermally conductive plastic.

9. A light emitting device in accordance with claim 4 wherein there is gap between the light emitting element and optical component.

10. A light emitting device in accordance with claim 5 wherein the gap is at least partially filled with a gas.

11. A light emitting device in accordance with claim 5 wherein the gap is at least partially filled with a thermal transfer gel.

12. A light emitting device including a light emitting element having a light emitting surface and an optical component comprising an optical material comprising quantum dots sealed within a structural member comprising single crystalline sapphire, the optical component being coupled to the light emitting element by a thermally conductive member.

13. (canceled)

14. (canceled)
